(19) United States
(12) Patent Application Publication
(10) Pub. No.: US 2022/0037179 A1
(43) Pub. Date: Feb. 3, 2022

(54) PACKAGING UNIT FOR SUBSTRATES

(71) Applicant: Heraeus Deutschland GmbH & Co. KG, Hanau (DE)

(72) Inventors: Hans-Jürgen Richter, Hanau (DE); Richard Wacker, Hanau (DE); Nadja Pelshaw, Hanau (DE); Yvonne Löwer, Hanau (DE)

(21) Appl. No.: 17/309,444

(22) PCT Filed: Nov. 21, 2019
(86) PCT No.: PCT/EP2019/082016

§ 371 Date: May 27, 2021

(30) Foreign Application Priority Data
Dec. 6, 2018 (EP) 18210737.5

(51) Int. Cl. H01L 21/673

(52) U.S. Cl. CPC H01L 21/67346; H01L 21/67366; H01L 21/67363

(57) ABSTRACT

The invention relates to a packaging unit for substrates, a packaging stack having packaging units of this type and a method for packaging substrates. The packaging unit for substrates comprises a first substrate, a spacer and a second substrate. The spacer is placed on the first substrate and the second substrate is placed on the spacer. A respective metal deposit is applied to a surface of the first substrate and to a surface of the second substrate and a respective adhesive point is arranged on the two metal deposits. The spacer is placed on the first substrate in such a way that the spacer is only in contact with the first substrate outside of the adhesive point. The spacer is bridge-shaped. At least the first substrate comprises a plurality of individual substrates arranged next to one another and the spacer borders the individual substrates.

### TECHNICAL FIELD

The present invention relates to a packaging unit for substrates, a packaging stack having such packaging units and a method for packaging substrates.

### BACKGROUND OF THE INVENTION

Ceramic circuit substrates are of interest in the field of high-power electronics in particular, owing to their high thermal conductivity, high dimensional stability or mechanical strength and their high insulation strength.

DE 10 2010 018 668 B4 discloses a packaging unit made up of a packaging for metal-ceramic substrates and a plurality of metal-ceramic substrates, in each case consisting of a ceramic layer and of a single metallization formed on at least one surface side of the ceramic layer and predetermined breaking lines running between the same.

DE 10 2012 106 087 B4 discloses a packaging unit for substrates, particularly for metal-ceramic substrates, consisting of a packaging with a lower packaging part produced from a flat material and a receptacle, which is formed by a depression in an upper base section of the lower packaging part, for a plurality of or at least one substrate stack or partial stack.

However, particularly for delicate substrates and in particular substrates with delicate surfaces or surface sections, these packagings can still be improved.

### SUMMARY OF THE INVENTION

It is therefore an object of the present invention to provide a packaging unit for substrates, using which even delicate substrates can be packaged safely.

This object is achieved by a packaging unit for substrates, a packaging stack having a multiplicity of such packaging units and a method for packaging substrates according to the independent claims. Advantageous embodiments and developments are to be drawn from the dependent claims and the following description.

The packaging unit for substrates comprises a first substrate, a spacer and a second substrate. The spacer is placed onto the first substrate and the second substrate is placed onto the spacer. A metal deposit is placed onto a surface of the first substrate and onto a surface of the second substrate in each case and one adhesive dot is arranged on each of the two metal deposits. The spacer is placed onto the first substrate in such a manner that the spacer is only in contact with the first substrate outside of the adhesive dot.

The substrate material may be any desired substrate material, which is not immediately finished completely for example and therefore first has to be stored reliably. The substrate can be constructed in a planiform manner and have a flat planar structure. For example, the substrate may be a starting material for manufacturing electronic modules in semiconductor technology.

The substrate has what is known as a metal deposit on its surface. The metal deposit, in other words a metal supply, may comprise a metal or a plurality of different metals in certain mixing ratios or consist of the same, depending on the intended purpose. The metal deposit may for example be suitable for a permanent, strong connection of components, for example in that it is connected or alloyed to the surface of components as a melt and solidifies after cooling or in that it is connected to the surface of components without melting, in the sense of a sintered material. The size and thickness of the metal deposit can also be varied, depending on the intended purpose.

An adhesive dot is arranged on the metal deposit. The adhesive dot can be used to fix an electronic component, for example, on the substrate, in order to facilitate a subsequent soldering or sintering process between the electronic component and the substrate. During soldering or sintering of the electronic component to the substrate, the adhesive dot may vaporize undegraded and/or volatilize whilst undergoing degradation, so that the adhesive dot does not leave behind any or any disruptive residues.

The packaging unit has a spacer, which can be positioned between two successive substrates in order to avoid a contact between the substrates. The spacer is placed onto the first substrate in such a manner that the spacer is only in contact with the first substrate outside of the adhesive dot. In other words, the spacer is not in contact with the adhesive dot, neither at the side nor at the surface of the adhesive dot. The spacer can be placed onto the first substrate in such a manner that it is also only in contact with the first substrate outside of the metal deposit. Preferably, the spacer is not in contact with the metal deposit, neither at the side nor at the surface of the metal deposit.

The first and second substrate can be stacked on top of one another in the vertical direction. In this case, it is important that the adhesive dot is not contacted or smeared. Therefore, the spacer can only be in contact with the substrate outside of the adhesive dot. In other words, the spacer can have at least one cutout, so that the spacer can be placed onto the surface of the first substrate without being in contact with the adhesive dot. The second substrate can be placed onto the spacer, wherein the spacer is in contact with an underside of the second substrate. The “underside” may be a surface of the substrate, on which neither metal deposit nor adhesive dot is placed. By contrast, an “upper side” may be a surface of the substrate, on which the metal deposit and the adhesive dot are applied.

The spacer may be smaller than or the same size as the substrate. In other words, the outer dimensions of the spacer may be at most as large as the outer dimensions of the substrate. More precisely, an outer circumference or an outer contour of the spacer may be smaller than or just as large as an outer circumference or an outer contour of the substrate.

The advantage of the packaging unit according to the invention lies in the fact that even delicate substrates can be packaged safely and in particular stacked in a space-saving manner without being in contact with the adhesive dot on the metal deposit. The packaging unit according to the invention makes it possible that the metal deposit and the adhesive dot can be applied onto the substrate directly after the production of the substrate by a producer or further processor of the substrate and the substrate with metal deposit and adhesive dot can readily be sent to a further processor or a user. In this manner, further processors or users of the substrate provided with metal deposit and adhesive dot can apply a further component directly onto the adhesive dot of the substrate and fasten the component, for example by means of a soldering or sintering method directly (without preprocessing for fixing the component). This so-called preapplication of the metal deposit and the adhesive dot makes it possible that a further component can be fastened on the substrate cost-effectively. Hitherto, the substrates were generally produced and sold without preapplied metal or solder deposits. Therefore, it is not necessary to separate the substrates from one another other than by means of continuous foils. In the case of a substrate with preapplied metal deposit, however, an adhesive dot is applied onto the substrate, which must not be smeared or contacted during the packaging and shipment of the parts. The spacer or the cutout of the spacer may contribute to it being possible to stack, store and/or transport the substrates without contacting the adhesive dot.

The first metal deposit and the first adhesive dot on the first substrate and the second metal deposit and the second adhesive dot on the second substrate may face in the vertical direction, that is to say perpendicularly to the superficial extent of the substrates, in the same direction. They can therefore be arranged either all on the upper sides of the two substrates or all on the undersides of the two substrates. It is of course also possible that one adhesive dot is arranged on the upper side of the one substrate and one adhesive dot is arranged on the underside of the other substrate, so that the adhesive dots face in different directions, i.e. either face towards one another or face away from one another.

The first and/or the second substrate may however also comprise one metal deposit and also one adhesive dot on both sides in each case. This means that at least one of the substrates can have a metal deposit and also an adhesive dot both on its upper side and on its underside. The cutout of the spacer can be set up in such a manner that the adhesive dot of the first substrate, which is directed upwards in the vertical direction, and the adhesive dot of the second substrate, which is directed downwards in the vertical direction, do not come into contact with one another.

In an embodiment, the first substrate is a first metal-ceramic substrate and the second substrate is a second metal-ceramic substrate.

In an embodiment, the first and the second metal-ceramic substrate comprise a ceramic layer and at least one metallization layer in each case, wherein the metal deposit is applied onto the metallization layer. In an embodiment, the metal-ceramic substrate comprises the ceramic layer and two metallization layers, wherein the metal deposit is applied onto one of the metallization layers. In an embodiment, the metal-ceramic substrate comprises a ceramic layer and two metallization layers and both metallization layers have an external surface, onto which a metal deposit is applied.

The term “metal-ceramic substrate” can be understood such that the substrate can be produced from ceramic and metallized by various methods, such as e.g. direct copper bonding (usually termed a DCB method), direct aluminium bonding (usually termed a DAB method) or active metal brazing (usually termed an AMB method). Suitable materials for the ceramic substrate are for example an oxide, a nitride, a carbide or a mixture or composite of at least two of these materials, particularly possibly doped aluminium-oxide or silicon-oxide ceramic. The composite material obtained after the metallization of the ceramic substrate is also termed a metal-ceramic substrate or metal-ceramic composite. If it was for example produced by a DCB method, the term “DCB substrate” is often also used.

A metallization of the ceramic substrate can for example be realized in that first a metal foil is oxidized, so that a metal oxide layer is formed on the surface thereof. The oxidized metal foil is placed onto the ceramic substrate and the ceramic substrate is heated with the oxidized metal foil. The metal-ceramic substrate may exhibit a strong bond of the metal coating on the ceramic surface, wherein this bond should also remain strong under sustained instances of temperature-fluctuation loading.

In the case of a metal that can be soldered, the metal deposit can be applied onto the metal-ceramic substrate by means of soldering, for example by vacuum soldering in an active atmosphere with formic acid activation. In the case of a metal that can be sintered, the metal deposit can be applied onto the metal-ceramic substrate by sintering or pre-sintering. The metal deposit can be applied on the metal-ceramic substrate in a defined volume, at a defined position and with a defined shape. In this manner, the metal-ceramic substrate can be processed further without metal paste printing and/or a cleaning process. This makes it possible that a further component, such as e.g. a chip can be applied onto the substrate or metal deposit in a simplified manner and fastened there for example without using auxiliaries, such as for example fluxes, cleaning agents and similar.

In an embodiment, the metal deposit comprises a metal that can be soldered or sintered or an alloy that can be soldered or sintered. The metal deposit can also be understood as a soldering or sintering deposit and have a certain volume or be a metal/alloy layer. The metal deposit can be a metal that can be soldered or sintered or an alloy that can be soldered or sintered.

The spacer is web-like. In other words, the spacer can have at least one cutout, preferably a multiplicity of cutouts and intermediate bridges or guide strips, which connect the cutouts. The cutouts may have an identical shape and the shape may be constructed in a rectangular, round, oval or similar manner. Each of the cutouts may also have different shapes. The cutouts can be used such that the adhesive dot on the metal deposit remains uncontacted and is therefore not smeared, in spite of the stacking of substrates and spacers.

In an embodiment, the spacer has a thickness between 200 and 1000 μm, preferably between 300 and 800 μm. The thickness of the spacer can be designed such that it corresponds at least to the height of the metal deposit together with the height of the adhesive dot. The thickness of the spacer can also be designed such that it additionally comprises a clearance distance. The clearance distance may for example be 50 to 100 μm. With or without clearance distance, the adhesive dot on the metal deposit can remain uncontacted and therefore not be smeared, in spite of the stacking of substrates and spacers. In another embodiment, if the metal deposit and the adhesive dots are arranged in such a manner on the underside of the one substrate and the upper side of the other substrate, that they face one another, the thickness of the spacer can be designed such that it corresponds at least to the height of the two metal deposits together with the height of the two adhesive dots with or without a clearance distance.

In an embodiment, the spacer is produced from plastic or cardboard. The spacer may be produced from roll goods. In this manner, the spacer can be produced cost-effectively and easily.

In an embodiment, the packaging unit comprises a further spacer, which is placed onto the second substrate. In this manner, a third substrate can be placed onto the further spacer. The further spacer can however also form an end of the packaging unit. Of course, the packaging unit can comprise a multiplicity of alternately arranged substrates and spacers.

In an embodiment, the spacers are identical in terms of design. The spacers may however also be designed differently for example depending on the size and position of the metal deposit and the adhesive dot on the respective substrate.

In an embodiment, the adhesive dots are smearable at room temperature. Smearable means that the adhesive dots may have started to dry after the application on the metal deposits for example, but not become solid or hard in air, but rather remain tacky or smudgy. The smearable adhesive dots are neither completely solid nor completely liquid. They may have a certain viscosity, so that a further component applied for example onto the adhesive dot cannot move independently or slip independently, even in the case of a position of the substrate at an angle of 90°.

In an embodiment, the two adhesive dots are configured in order to fix one electronic component on the first substrate and on the second substrate in each case. The metal-ceramic substrate may be suitable for an electronic use, in which an electronic component, for example a chip, a switch, an illumination element, a capacitor, a resistor or similar is applied.

In an embodiment, the first substrate and/or the second substrate is a direct copper bonding (DCB) or a direct aluminium bonding (DAB) substrate. The DCB or DAB substrate may enable a good electrical and thermal connection of electronic components and chips via copper or aluminium.

At least the first substrate comprises a multiplicity of individual substrates arranged next to one another and the spacer edges the individual substrates. The substrate may be present in the form of an individual substrate. Alternatively, it is also possible that the substrate has one or more predetermined breaking lines (preferably running linearly), which divide the substrate into two or more regions. The spacer may run in a linear or grid-shaped manner between the individual substrates.

The present invention furthermore comprises a packaging stack which comprises a multiplicity of packaging units stacked on top of one another. Due to a relatively flat configuration of the substrate and the spacer, it may be possible that a multiplicity of substrates and spacers can be stacked on top of one another in a space-saving manner. The grid-shaped spacers may make it possible that the adhesive dots on the metal deposits remain free of contact in spite of the stacking of a plurality of substrates and spacers. The packaging stack can, depending on the intended purpose and storage capacity, have any desired number of packaging units and therefore any desired number of substrates and spacers.

The present invention furthermore comprises a method for packaging substrates.

The method comprises the following steps:
providing a first substrate,
placing a spacer onto the first substrate, and
placing a second substrate onto the spacer.

A metal deposit is placed onto a surface of the first substrate and onto a surface of the second substrate in each case and one adhesive dot is arranged on each of the two metal deposits. Furthermore, the spacer is placed onto the first substrate in such a manner that the spacer is only in contact with the first substrate outside of the adhesive dot.

Further features, advantages and application possibilities of the present invention result from the following description, the exemplary embodiments and the figures. All described and/or pictorially illustrated features can be combined with one another independently of their representation in individual claims, figures, sentences or paragraphs. In the figures, the same reference numbers stand for the same or similar objects.

### SHORT DESCRIPTION OF THE FIGURES

FIG. 1 shows a packaging unit according to an embodiment.

FIG. 2 shows a packaging unit according to an embodiment.

FIG. 3 shows a metal-ceramic substrate according to an embodiment.

FIG. 4 shows a packaging stack according to an embodiment.

### DETAILED DESCRIPTION OF EXEMPALRY EMBODIMENTS

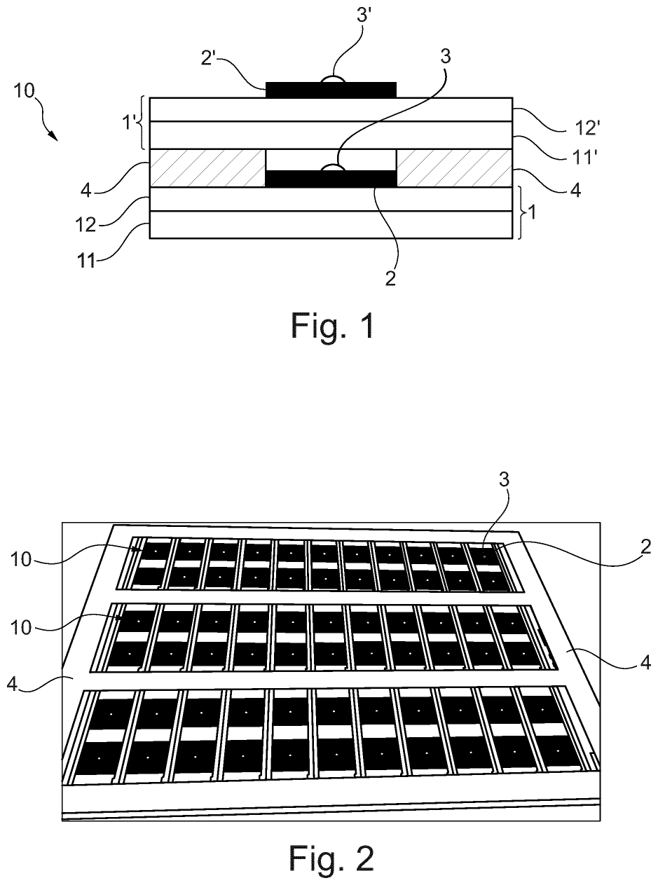

FIG. 1 and FIG. 2 show a packaging unit 10 for metal-ceramic substrates 1, 1′. The packaging unit 10 comprises a first substrate 1, a spacer 4 and a second substrate 1′. The spacer 4 is placed onto the first substrate 1 and the second substrate 1′ is placed onto the spacer 4.

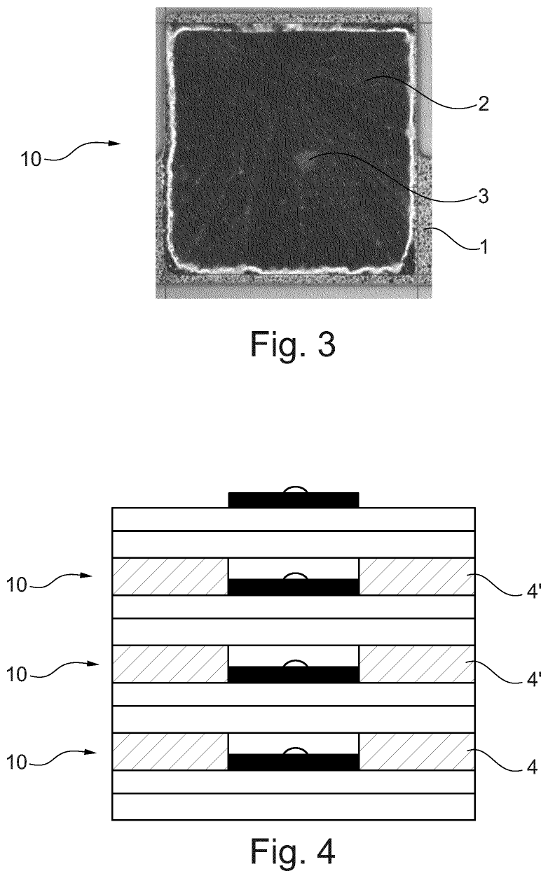

The metal-ceramic substrate 1, 1′ can be produced by a direct copper bonding (DCB) method or direct aluminium bonding (DAB) method and comprise a multiplicity of individual substrates arranged next to one another. The metal-ceramic substrate 1, 1′ has a ceramic layer 11, 11′ and at least one metallization layer 12, 12′. The metal-ceramic substrate 1, 1′ preferably has two metallization layers in all, namely the metallization layer 12, 12′ and a further metallization layer, which is not shown, on the other side of the ceramic layer 11, 11′. As also shown in FIG. 3, one metal deposit 2, 2′ is applied onto an upper side of the metallization layer 12 of the two substrates 1, 1′ in each case and one adhesive dot 3, 3′ is arranged on each of the two metal deposits 2, 2′. The metal deposit 2, 2′ comprises a metal that can be soldered or sintered or an alloy that can be soldered or sintered. The adhesive dots 3, 3′ are tacky and smearable at room temperature or in air. The adhesive dots 3, 3′ face in the same direction, upwards here, i.e. the two adhesive dots 3, 3′ are both constructed on the upper sides of the respective substrates 1, 1′. An electronic component, for example a chip, lamp, resistor, capacitor, etc. can be applied on the respective adhesive dots 3, 3′.

The spacer 4 is of web-like or grid-shaped construction and placed onto the first substrate 1 in such a manner that the spacer 4 is only in contact with the first substrate 1 outside of the adhesive dot 3. The spacer 4 can be produced from rollable plastic or cardboard. A thickness or height of the spacer 4 can be between 200 and 1000 μm, preferably between 300 and 800 μm, so that a sum of metal deposit 2, adhesive dot 3 and, if appropriate, clearance distance does not fall below a lower limit of the thickness of the spacer 4.

The upper limit of the thickness of the spacer 4 can further be designed such that a starting material for the spacer 4 can be rolled. If at least one substrate 1, 1′ comprises a multiplicity of individual substrates arranged next to one another, the spacer 4 edges the individual substrates, so that the adhesive dots 3 are not contacted (see FIG. 2).

As shown in FIG. 4, the packaging unit 10 can furthermore have a further spacer 4′, which is placed onto the second substrate 1′. A packaging stack can be realized in this manner, which comprises a multiplicity of packaging units 10 stacked on top of one another.

### Preferred Embodiments

1. A packaging unit (10) for substrates (1, 1′), comprising:
a first substrate (1),
a spacer (4), and
a second substrate (1′),
wherein the spacer (4) is placed onto the first substrate (1) and the second substrate (1′) is placed onto the spacer (4),
wherein a metal deposit (2, 2′) is placed onto a surface of the first substrate (1) and onto a surface of the second substrate (1′) in each case and one adhesive dot (3, 3′) is arranged on each of the two metal deposits (2, 2′), and
wherein the spacer (4) is placed onto the first substrate (1) in such a manner that the spacer (4) is only in contact with the first substrate (1) outside of the adhesive dot (3).

2. The packaging unit (10) according to the preceding embodiment, wherein the first substrate (1) is a first metal-ceramic substrate and the second substrate (1′) is a second metal-ceramic substrate.

3. The packaging unit (10) according to the preceding embodiment, wherein the first and the second metal-ceramic substrate (1, 1′) comprise a ceramic layer (11, 11′) and at least one metallization layer (12, 12′) in each case and the metallization layer (12, 12′) has the surface onto which the metal deposit (2, 2′) is applied.

4. The packaging unit (10) according to one of the preceding embodiments, wherein the metal deposit (2, 2′) comprises a metal that can be soldered or sintered or an alloy that can be soldered or sintered.

5. The packaging unit (10) according to one of the preceding embodiments, wherein the spacer (4) is web-like.

6. The packaging unit (10) according to one of the preceding embodiments, wherein the spacer (4) has a thickness between 200 and 1000 μm and preferably a thickness between 300 and 800 μm.

7. The packaging unit (10) according to one of the preceding embodiments, wherein the spacer (4) is produced from plastic or cardboard.

8. The packaging unit (10) according to one of the preceding embodiments, furthermore comprising a further spacer (4′), which is placed onto the second substrate (1′).

9. The packaging unit (10) according to the preceding embodiment, wherein the spacers (4) are identical in terms of design.

10. The packaging unit (10) according to one of the preceding embodiments, wherein the adhesive dots (3, 3′) are smearable at room temperature.

11. The packaging unit (10) according to one of the preceding embodiments, wherein the adhesive dots (3, 3′) are configured in order to fix one electronic component on the first substrate (1) and on the second substrate (1′) in each case.

12. The packaging unit (10) according to one of the preceding embodiments, wherein the first substrate (1) and/or the second substrate (1′) is a direct copper bonding substrate or a direct aluminium bonding substrate.

13. The packaging unit (10) according to one of the preceding embodiments, wherein at least the first substrate (1) comprises a multiplicity of individual substrates arranged next to one another and the spacer (4) edges the individual substrates.

14. A packaging stack comprising a multiplicity of packaging units (10) according to one of the preceding embodiments stacked on top of one another.

15. A method for packaging substrates (1, 1′), comprising the following steps:
providing a first substrate (1),
placing a spacer (4) onto the first substrate (1), and
placing a second substrate (1′) onto the spacer (4),
wherein a metal deposit (2, 2′) is placed onto a surface of the first substrate (1) and onto a surface of the second substrate (1′) in each case and one adhesive dot (3, 3′) is arranged on each of the two metal deposits (2, 2′), and
wherein the spacer (4) is placed onto the first substrate (1) in such a manner that the spacer (4) is only in contact with the first substrate (1) outside of the adhesive dot (3).

Additionally, it is noted that “comprising” and “having” does not exclude other elements or steps and “a” or “an” do not exclude a multiplicity. Furthermore, it may be pointed out that features or steps, which have been described with reference to one of the above exemplary embodiments, can also be used in combination with other features or steps of other above-described exemplary embodiments. Reference numbers in the claims are not to be seen as limiting.

1. A packaging unit for substrates, comprising:
a first substrate,
a spacer, and
a second substrate,
wherein the spacer is placed onto the first substrate and the second substrate is placed onto the spacer,
wherein a first metal deposit is placed onto a surface of the first substrate and a second metal deposit is placed onto a surface of the second substrate in each case and one adhesive dot is arranged on each of the two metal deposits, and
wherein the spacer is placed onto the first substrate in such a manner that the spacer is only in contact with the first substrate outside of the adhesive dot,
wherein the spacer is web-like, and
wherein at least the first substrate comprises a multiplicity of individual substrates arranged next to one another and the spacer edges the individual substrates.

2. The packaging unit according to claim 1, wherein the first substrate is a first metal-ceramic substrate and the second substrate is a second metal-ceramic substrate.

3. The packaging unit according to claim 2, wherein the first and the second metal-ceramic substrate comprise a ceramic layer and at least one metallization layer in each case and the metallization layer has the surface onto which the metal deposit is applied.

4. The packaging unit according to claim 1, wherein the metal deposits comprise a metal that can be soldered or sintered or an alloy that can be soldered or sintered.

5. The packaging unit according to claim 1, wherein the spacer has a thickness between 200 and 1000 μm.

6. The packaging unit according to claim 1, wherein the spacer is produced from plastic or cardboard.

7. The packaging unit according to claim 1, furthermore comprising a second spacer, which is placed onto the second substrate.

8. The packaging unit according to claim 7, wherein the spacer and the second spacer are identical in terms of design.

9. The packaging unit according to claim 1, wherein the adhesive dots are smearable at room temperature.

10. The packaging unit according to claim 1, wherein the adhesive dots are configured in order to fix one electronic component on the first substrate and on the second substrate in each case.

11. The packaging unit according to claim 1, wherein the first substrate and/or the second substrate is a direct copper bonding substrate or a direct aluminium bonding substrate.

12. A packaging stack comprising a multiplicity of packaging units according to claim 1 stacked on top of one another.

13. A method for packaging substrates, comprising the following steps:
providing a first substrate,
placing a spacer onto the first substrate, and
placing a second substrate onto the spacer,
wherein a first metal deposit is placed onto a surface of the first substrate and a second metal deposit is placed onto a surface of the second substrate in each case and one adhesive dot is arranged on each of the two metal deposits,
wherein the spacer is placed onto the first substrate in such a manner that the spacer is only in contact with the first substrate outside of the adhesive dot,
wherein the spacer is web-like, and
wherein at least the first substrate comprises a multiplicity of individual substrates arranged next to one another and the spacer edges the individual substrates.

14. The packaging unit according to claim 1, wherein the spacer has a thickness between 300 and 800 μm.
